(19) United States
(12) Patent Application Publication
(10) Pub. No.: US 2017/0200686 A1
(43) Pub. Date: Jul. 13, 2017

(54) SEMICONDUCTOR DEVICE AND MANUFACTURING METHOD THEREOF

(71) Applicant: Amkor Technology, Inc., Tempe, AZ (US)

(72) Inventors: Sung Geun Kang, Bucheon-si (KR); Ju Hoon Yoon, Namyangju-si (KR); In Rak Kim, Incheon (KR)

(21) Appl. No.: 15/149,038

(22) Filed: May 6, 2016

(30) Foreign Application Priority Data
Jan. 11, 2016 (KR) 10-2016-0003231

(51) Int. Cl. H01L 23/00; H01L 23/31; H01L 21/78; H01L 21/762; H01L 21/56

(52) U.S. Cl. CPC H01L 24/05; H01L 21/76256; H01L 21/568; H01L 21/561; H01L 21/78; H01L 23/3128; H01L 2021/60022

(57) ABSTRACT

Disclosed are a semiconductor device and a manufacturing method thereof, which can easily increase the number of input/output pads by increasing regions for forming the input/output pads such that a redistribution layer is formed to extend up to an encapsulant. In one embodiment, the manufacturing method includes preparing a wafer by sequentially forming an oxide layer, a semiconductor layer and a back end of line (BEOL) layer on a wafer substrate, dicing the wafer to divide the wafer into individual semiconductor chips, mounting the semiconductor chip on one surface of a carrier by flipping the semiconductor chips and removing the wafer substrate from the semiconductor chips, encapsulating the one surface of the carrier and the semiconductor chips using an encapsulant and then removing the carrier, forming a redistribution layer to be electrically connected to the BEOL layer exposed to the outside while removing the carrier, and forming conductive bumps to be electrically connected to be electrically connected to the redistribution layer.

### CROSS-REFERENCE TO RELATED APPLICATIONS

The present application makes reference to, claims priority to, and claims the benefit of Korean Patent Application No. 10-2016-0003231, filed on Jan. 11, 2016, the contents of which are hereby incorporated herein by reference, in their entirety.

### FIELD

Certain embodiments of the disclosure relate to a semiconductor device and a manufacturing method thereof.

### BACKGROUND

In general, a semiconductor device includes a semiconductor die manufactured by processing a wafer and forming an integrated circuit (IC) on the wafer.

In a case of using the semiconductor die as an RF device, when the semiconductor device transmits a signal through radio frequency, the loss of power may be caused due to the wafer substrate remaining after processing the wafer, and the leakage of current may also occur.

### BRIEF SUMMARY

The present invention provides a semiconductor device and a manufacturing method thereof, which can easily increase the number of input/output pads by increasing regions for forming the input/output pads such that a redistribution layer is formed to extend up to an encapsulant.

The present invention also provides a semiconductor device and a manufacturing method thereof, which can prevent the leakage of current and can reduce the loss of power by completely removing the remaining wafer substrate using an oxide layer formed to cover semiconductor dies.

The above and other objects of the present invention will be described in or be apparent from the following description of the preferred embodiments.

According to an aspect of the present invention, there is provided a manufacturing method of a semiconductor device, the manufacturing method including preparing a wafer by sequentially forming an oxide layer, a semiconductor layer and a back end of line (BEOL) layer on a wafer substrate, dicing the wafer to divide the wafer into individual semiconductor chips, mounting the semiconductor chip on one surface of a carrier by flipping the semiconductor chips and removing the wafer substrate from the semiconductor chips, encapsulating the one surface of the carrier and the semiconductor chips using an encapsulant and then removing the carrier, forming a redistribution layer to be electrically connected to the BEOL layer exposed to the outside while removing the carrier, and forming conductive bumps to be electrically connected to be electrically connected to the redistribution layer.

According to another aspect of the present invention, there is provided a semiconductor device including a redistribution layer, a back end of line (BEOL) layer electrically connected to the redistribution layer, a semiconductor die electrically connected to the BEOL layer, an oxide layer covering one surface of the semiconductor die, an encapsulant encapsulating the oxide layer, the semiconductor die, the BEOL layer and one surface of the redistribution layer, and conductive bumps formed on the other surface of the redistribution layer and electrically connected to the redistribution layer.

As described above, in the semiconductor device and the manufacturing method thereof, the number of input/output pads can easily increase by increasing a region for forming the input/output pads such that a redistribution layer is formed to extend up to an encapsulant.

In addition, in the semiconductor device and the manufacturing method thereof, the leakage of current can be prevented and the loss of power can be reduced by completely removing the remaining wafer substrate using an oxide layer formed to cover semiconductor dies.

### BRIEF DESCRIPTION OF SEVERAL VIEWS OF THE DRAWINGS

FIG. 1 is a flowchart illustrating a manufacturing method of a semiconductor device according to an embodiment of the present invention;

FIGS. 2A to 2J are cross-sectional views illustrating various steps of the manufacturing method of the semiconductor device illustrated in FIG. 1;

FIG. 3 is a flowchart illustrating a manufacturing method of a semiconductor device according to another embodiment of the present invention; and

FIGS. 4A to 4F are cross-sectional views illustrating various steps of the manufacturing method of the semiconductor device illustrated in FIG. 3.

### DETAILED DESCRIPTION

Various aspects of the present disclosure may be embodied in many different forms and should not be construed as being limited to the example embodiments set forth herein. Rather, these example embodiments of the disclosure are provided so that this disclosure will be thorough and complete and will convey various aspects of the disclosure to those skilled in the art.

In the drawings, the thickness of layers and regions are exaggerated for clarity. Here, like reference numerals refer to like elements throughout. As used herein, the term “and/or” includes any and all combinations of one or more of the associated listed items. In addition, the terminology used herein is for the purpose of describing particular embodiments only and is not intended to be limiting of the disclosure. As used herein, the singular forms are intended to include the plural forms as well, unless the context clearly indicates otherwise. It will be further understood that the terms “comprises,” “comprising,” “includes,” and/or “including,” when used in this specification, specify the presence of stated features, numbers, steps, operations, elements, and/or components, but do not preclude the presence or addition of one or more other features, numbers, steps, operations, elements, components, and/or groups thereof.

It will be understood that, although the terms first, second, etc. may be used herein to describe various members, elements, regions, layers and/or sections, these members, elements, regions, layers and/or sections should not be limited by these terms. These terms are only used to distinguish one member, element, region, layer and/or section from another. Thus, for example, a first member, a first element, a first region, a first layer and/or a first section discussed below could be termed a second member, a second element, a second region, a second layer and/or a second section without departing from the teachings of the present disclosure. Reference will now be made in detail to the present embodiments of the present invention, examples of which are illustrated in the accompanying drawings.

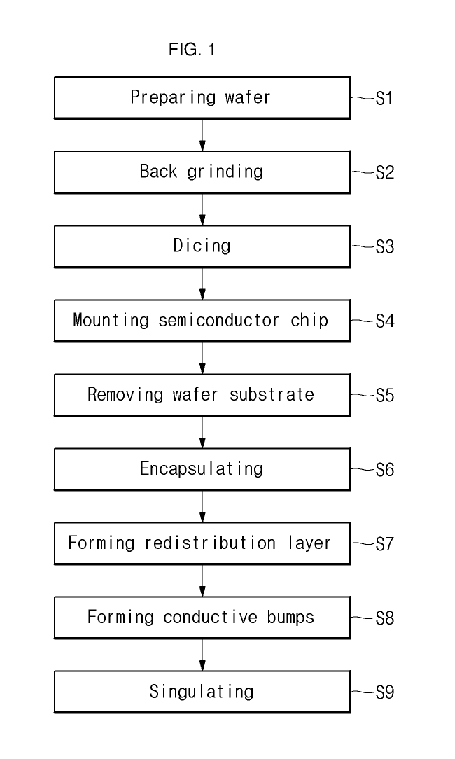

Referring to FIG. 1, a flowchart illustrating a manufacturing method of a semiconductor device (100) according to an embodiment of the present invention is illustrated.

As illustrated in FIG. 1, the manufacturing method of the semiconductor device (100) includes preparing a wafer (S1), back grinding (S2), dicing (S3), mounting semiconductor chips (S4), removing a wafer substrate (S5), encapsulating (S6), forming a redistribution layer (S7), forming conductive bumps (S8) and singulating (S9).

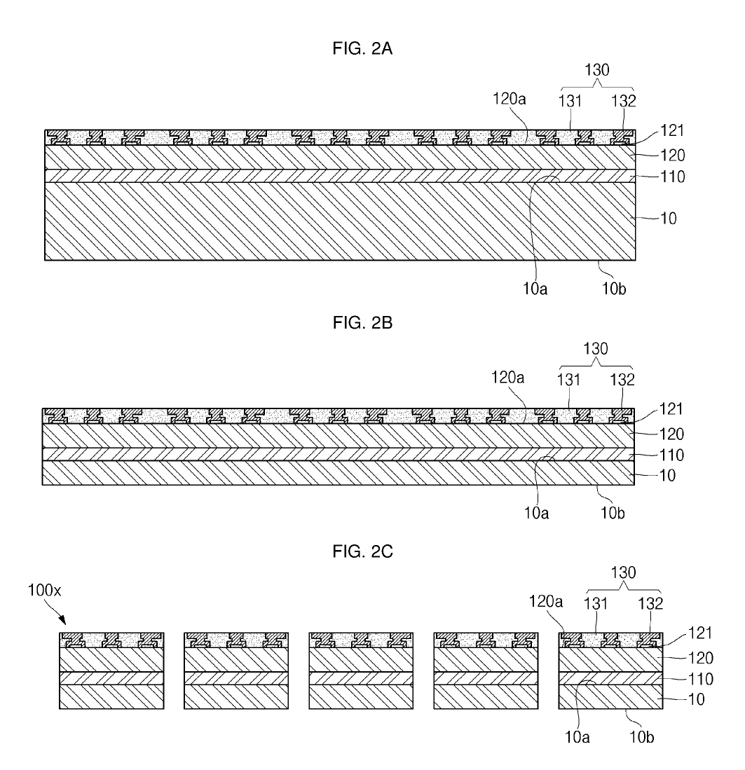

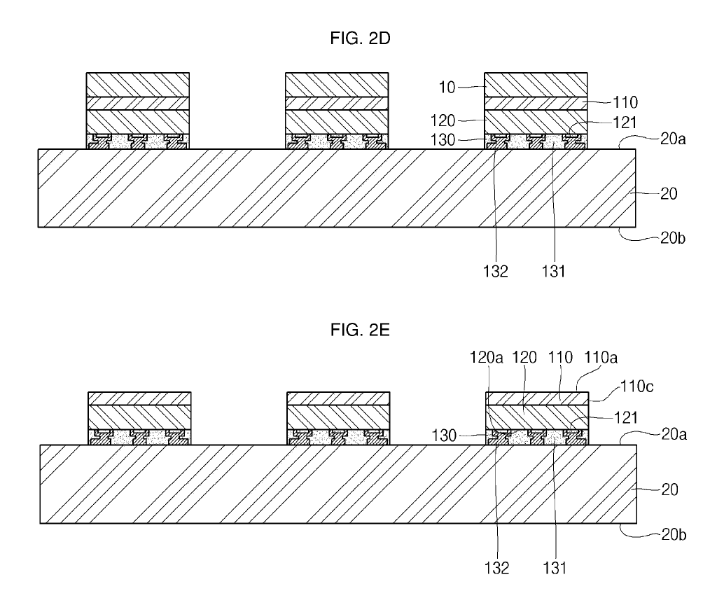

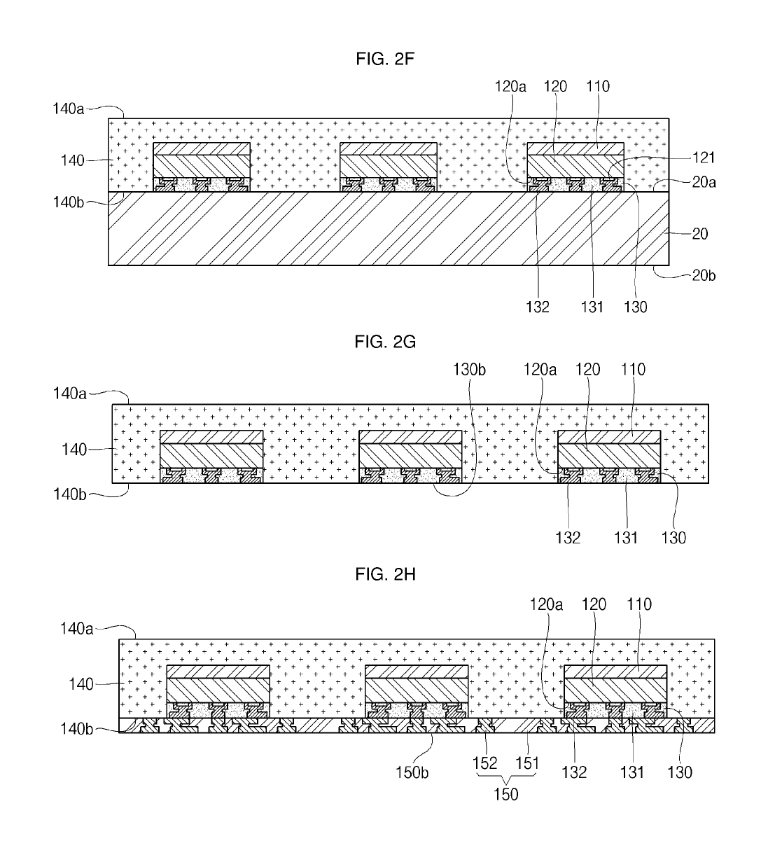

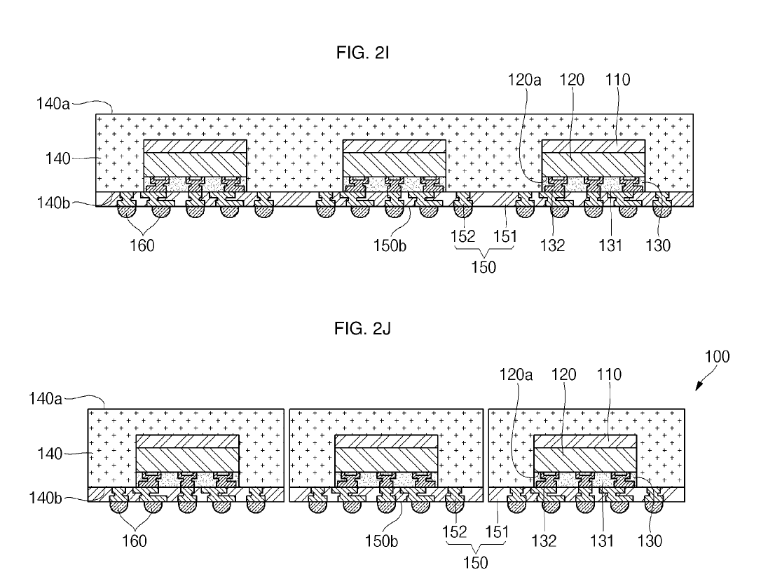

Referring to FIGS. 2A to 2J, cross-sectional views illustrating various steps of the manufacturing method of the semiconductor device (100) illustrated in FIG. 1 are illustrated.

Hereinafter, the manufacturing method of the semiconductor device will be described with reference to FIG. 1 and FIGS. 2A to 2J.

As illustrated in FIG. 2A, in the preparing of the wafer (S1), the wafer is prepared on a wafer substrate 10, the wafer including an oxide layer 110, a semiconductor layer 120 and a back end of line (BEOL) layer 130 sequentially formed thereon.

The oxide layer 110 may be formed on a first surface 10a of the wafer substrate 10 to a predetermined thickness. The wafer substrate 10 may be a silicon substrate, but aspects of the present invention are not limited thereto. The oxide layer 110 may be a silicon oxide layer having a good interface characteristic between the wafer substrate 10 made of silicon and the semiconductor layer 120 to be described later. The oxide layer 130 is formed on the entire top region of the wafer substrate 10 using one selected from the group consisting of thermal oxidation, chemical vapor deposition (CVD), physical vapor deposition (PVD) and equivalents thereof. The oxide layer 110 may be interposed between the semiconductor layer 120 and the wafer substrate 10. The oxide layer 110 may be provided to prevent the leakage of current.

The semiconductor layer 120 is a semiconductor having a plurality of integrated circuits therein, and may be substantially shaped of a plate. Terminals 121 can be interfaces for the plurality of integrated circuits in semiconductor layer 120. Terminals 121 may be electrically connected to first redistributions 132 of the BEOL layer 130. The semiconductor layer 120 may be interposed between the oxide layer 110 and the BEOL layer 130.

The BEOL layer 130 includes a first dielectric layer 131 and the first redistributions 132. The BEOL layer 130 is formed to entirely cover the first surface 120a of the semiconductor layer 120.

The BEOL layer 130 includes the first dielectric layer 131 formed to entirely cover the semiconductor layer 120, opening regions formed by a photolithographic etching process and/or a laser process, and the first redistributions 132 formed in exposed regions of the opening regions. Here, terminals 121 may be exposed through the opening region, and the first redistributions 132 may be formed on the semiconductor layer 120 and the first dielectric layer 131 to make contact with or to be electrically connected to the terminals 121. The first redistributions 132 may be formed in various patterns to be electrically connected to terminals 121 of the semiconductor layer 120 and may include a plurality of first redistributions.

The first dielectric layer 131 may be one selected from the group consisting of a silicon oxide layer, a silicon nitride layer and equivalents thereof, but aspects of the present invention are not limited thereto. The first redistributions 132 may be formed by an electroless plating process for a seed layer made of gold, silver, nickel, titanium and/or tungsten, an electroplating process using copper, etc., and a photolithographic etching process using a photoresist, but aspects of the present invention are not limited thereto.

In addition, the first redistributions 132 may be made of not only copper but one selected from the group consisting of a copper alloy, aluminum, an aluminum alloy, iron, an iron alloy and equivalents thereof, but aspects of the present invention are not limited thereto. Further, the processes for forming the first dielectric layer 131 and the first redistributions 132 may be repeatedly performed multiple times, thereby completing the BEOL layer 130 having a multi-layered structure. In one example, First redistributions 132 can comprise bond pads exposed by the opening regions of first dielectric layer 131. In addition, the BEOL layer 130 is a redistribution layer formed by a fabrication (FAB) process. Specifically, the first redistributions 132 may be formed in a fine linewidth or thickness.

As illustrated in FIG. 2B, in the back grinding (S2), the second surface 10b of the wafer substrate 10, which is opposite to the first surface 10a on which the oxide layer 110, the semiconductor layer 120 and the BEOL layer 130 are formed, may be removed by grinding the second surface 10b. The wafer substrate 10 may be diced to yield individual semiconductor chips 100x to then be grinded such that it remains by a predetermined thickness to facilitate handling. The predetermined thickness of the remaining wafer substrate 10 may correspond to a thickness of the wafer substrate 10 to be removed by etching in the removing of the wafer substrate (S5), which will be described below.

As illustrated in FIG. 2C, in the dicing (S3), the wafer substrate 10 having the oxide layer 110, the semiconductor layer 120 and the BEOL layer 130 stacked thereon is diced to divide the wafer substrate 10 into the individual semiconductor chips 100x. That is to say, in the dicing (S3), the semiconductor layer 120 is diced to then be divided into the individual semiconductor chips 100x including individual semiconductor dies 120 (Throughout the specification, different terms, such as semiconductor layer and semiconductor dies, are interchangeably used and are denoted by the same reference numeral.) In addition, since the semiconductor chips 100x are separated by dicing, lateral surfaces of the wafer substrate 10, the oxide layer 110, the semiconductor dies 120 and the BEOL layer 130 may be positioned on the same plane. The dicing may be performed by blade dicing or using a dicing tool, but aspects of the present invention are not limited thereto. The semiconductor dies 120 may be radio frequency (RF) devices.

As illustrated in FIG. 2D, in the mounting of the semiconductor chips (S4), the plurality of individual semiconductor chips 100x may be mounted on the carrier 20 to be spaced apart from each other. The carrier 20 has a planar first surface 20a and a second surface 20b opposite to the first surface 20a, and the individual semiconductor chips 100x may be mounted on the first surface 20a of the carrier 20 to be spaced a predetermined distance apart from each other. Here, the respective semiconductor chips 100x may be flipped such that the BEOL layer 130 is brought into contact with the first surface 20a of the carrier 20 to then be mounted thereon. The carrier 20 may be made of one selected from the group consisting of silicon, low-grade silicon, glass, silicon carbide, sapphire, quartz, ceramic, metal oxide, metal and equivalents thereof, but aspects of the present invention are not limited thereto.

As illustrated in FIG. 2E, in the removing of the wafer substrate (S5), the wafer substrate 10 is removed from the plurality of semiconductor chips 100x, thereby exposing the oxide layer 110 to the outside. That is to say, the wafer substrate 10 is removed, so that the first surface 110a of the oxide layer 110 is exposed to the outside. In the removing of the wafer substrate (S5), the remaining wafer substrate 10 may be completely removed by a dry and/or wet etching process. The wafer substrate 10 may be removed in such a manner, thereby preventing the loss of power from occurring from the wafer substrate 10.

As illustrated in FIGS. 2F and 2G, in the encapsulating (S6), the plurality of semiconductor chips 100x mounted on the carrier 20 and the first surface 20a of the carrier 20 are encapsulated by the encapsulant 140 so as to be completely covered. The encapsulant 140 is formed to completely cover the first surface 20a of the carrier 20, the oxide layer 110, the semiconductor dies 120 and the BEOL layer 130. That is to say, the encapsulant 140 is formed on the first surface 20a of the carrier 20 to completely cover the individual semiconductor chips 100x mounted on the first surface 20a of the carrier 20. The encapsulant 140 has a planar first surface 140a and a second surface 140b opposite to the first surface 140a and being in contact with the first surface 20a of the carrier 20. The plurality of semiconductor chips 100x spaced apart from each other can be electrically protected from external circumstances by the encapsulant 140.

The encapsulating (S6) may be performed by one selected from the group consisting of general transfer molding, compression molding, injection molding and equivalents thereof, but aspects of the present invention are not limited thereto. The encapsulant 140 may be general epoxy, film, paste and equivalents thereof, but aspects of the present invention are not limited thereto.

In addition, after forming the encapsulant 140, the carrier 20 is removed to expose the second surface 130b of the BEOL layer 130 brought into contact with the first surface 20a of the carrier 20 and the second surface 140b of the encapsulant 140 to the outside.

As illustrated in FIG. 2H, in the forming of the redistribution layer (S7), the redistribution layer 150 is formed to cover the second surface 130b of the BEOL layer 130 and the second surface 140b of the encapsulant 140 so as to be electrically connected to the BEOL layer 130 exposed to the outside. The redistribution layer 150 includes a second dielectric layer 151 and second redistributions 152.

The redistribution layer 150 is formed by forming the second dielectric layer 151 to cover the second surface 130b of the BEOL layer 130 and the second surface 140b of the encapsulant 140, forming opening regions by a photolithographic etching process and/or a laser process, and forming the second redistributions 152 in regions exposed to the outside through the opening regions. Here, the first redistributions 132 of the BEOL layer 130 are exposed through the opening regions. In addition, the second redistributions 152 may be formed on the second surface 130b of the BEOL layer 130 to be brought into contact with and electrically connected to the first redistributions 132 exposed to the outside through the opening regions. In addition, the second redistributions 152 electrically connected to the first redistributions 132 may extend to the second surface 140b of the encapsulant 140. The second redistributions 152 may be formed in various patterns to be electrically connected to the BEOL layer 130 and may include a plurality of second redistributions. In addition, the redistribution layer 150 may be formed to extend to the second surface 140b of the encapsulant 140. The redistribution layer 150 may be formed by changing positions of the bond pads 121 of the semiconductor dies 120 or changing the number of input/output (I/O) pads. Further, since the redistribution layer 150 is formed to extend to the second surface 140b of the encapsulant 140, the number of I/O pads can be easily increased by increasing areas for forming the I/O pads.

The second dielectric layer 151 may be one selected from the group consisting of a silicon oxide layer, a silicon nitride layer and equivalents thereof, but aspects of the present invention are not limited thereto. The second dielectric layer 151 may prevent electrical short circuits between each of the second redistributions 152. The second redistributions 152 may be formed by an electroless plating process for a seed layer made of gold, silver, nickel, titanium and/or tungsten, an electroplating process using copper, etc., and a photolithographic etching process using a photoresist, but aspects of the present invention are not limited thereto.

In addition, the second redistributions 152 may be made of not only copper but one selected from the group consisting of a copper alloy, aluminum, an aluminum alloy, iron, an iron alloy and equivalents thereof, but aspects of the present invention are not limited thereto. The second redistributions 152 may be exposed to the second surface 150b of the redistribution layer 150. Further, the processes for forming the second dielectric layer 151 and the second redistributions 152 may be repeatedly performed multiple times, thereby completing the redistribution layer 150 having a multi-layered structure.

As illustrated in FIG. 2I, in the forming of the conductive bumps (S8), a plurality of conductive bumps 160 are formed to make contact with or to be electrically connected to the plurality of second redistributions 152 exposed to the second surface 150b of the redistribution layer 150. The conductive bumps 160 are electrically connected to the semiconductor dies 120 through the redistribution layer 150 and the BEOL layer 130. The conductive bumps 160 may include conductive fillers, copper fillers, conductive balls, solder balls or copper balls, but aspects of the present invention are not limited thereto.

When the semiconductor device 100 is mounted on an external device, such as a mother board, the conductive bumps 160 may be used as electrical connection means between the semiconductor device 100 and the external device.

As illustrated in FIG. 2J, in the singulating (S9), the encapsulant 140 and the redistribution layer 150 are diced to be divided into individual semiconductor devices 100 having one or more semiconductor dies 120.

The semiconductor device 100 may easily increase the number of I/O pads by increasing the regions for forming the I/O pads such that the redistribution layer 150 extends to the second surface 140b of the encapsulant 140. In addition, the semiconductor device 100 may completely remove the remaining wafer substrate from the oxide layer 110, thereby preventing the leakage of current and reducing the loss of power.

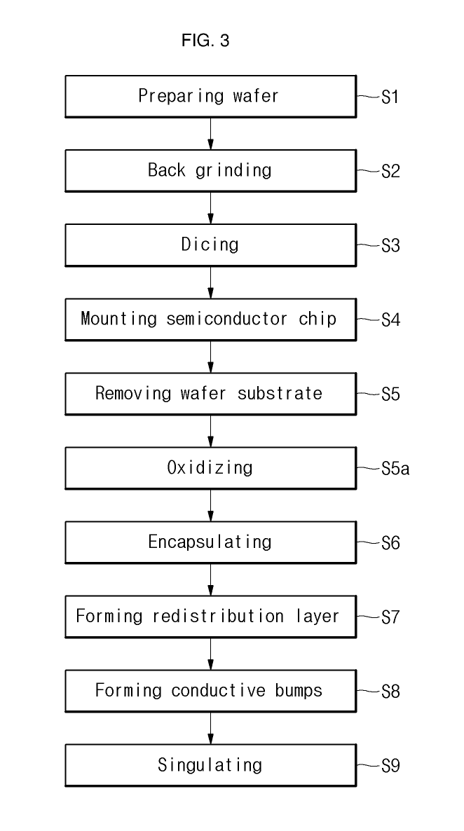

Referring to FIG. 3, a flowchart illustrating a manufacturing method of a semiconductor device according to another embodiment of the present invention is illustrated.

The manufacturing method of the semiconductor device (200) illustrated in FIG. 3 includes preparing a wafer (S1), back grinding (S2), dicing (S3), mounting semiconductor chips (S4), removing a wafer substrate (S5), oxidizing (S5a), encapsulating (S6), forming a redistribution layer (S7), forming conductive bumps (S8) and singulating (S9).

The preparing of the wafer (S1), the back grinding (S2), the dicing (S3), the mounting of the semiconductor chips (S4), and the removing of the wafer substrate (S5), illustrated in FIG. 3, are the same as the corresponding steps in the manufacturing method of the semiconductor device 100 illustrated in FIGS. 1 and 2A to 2E. Therefore, the following description will focus on steps of oxidizing (S5a), encapsulating (S6), forming a redistribution layer (S7), forming conductive bumps (S8) and singulating (S9).

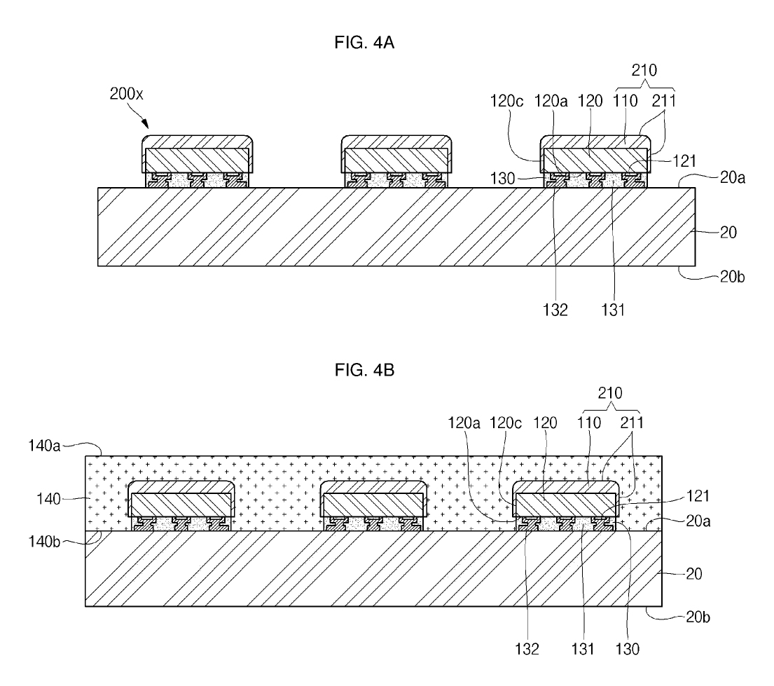

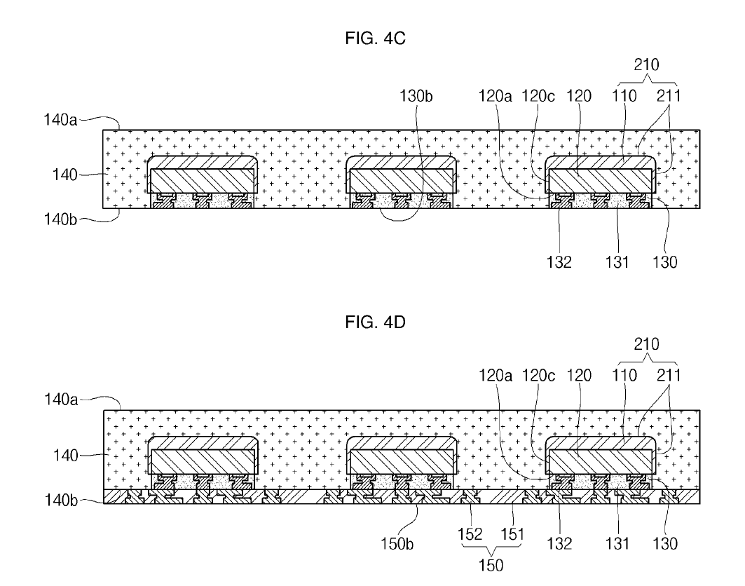

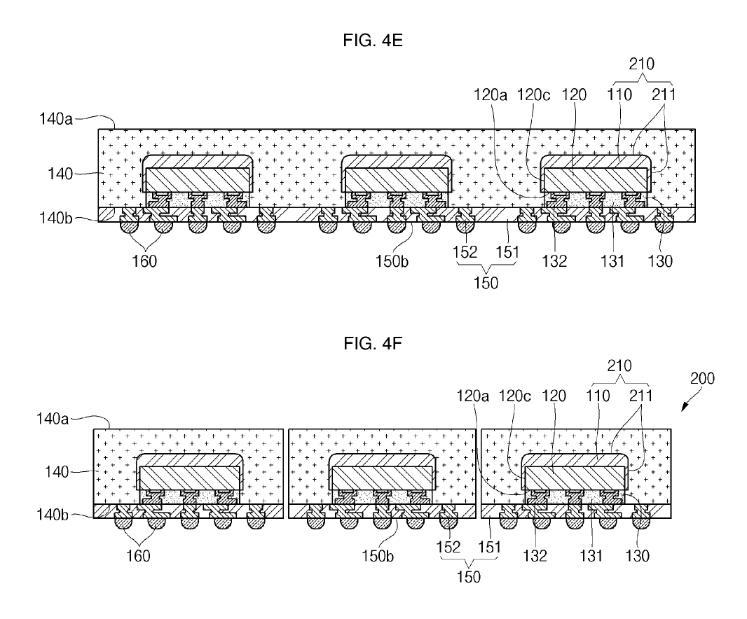

Referring to FIGS. 4A to 4F, cross-sectional views illustrating the manufacturing method of the semiconductor device (200) illustrated in FIG. 3, including various steps of oxidizing (S5a), encapsulating (S6), forming a redistribution layer (S7), forming conductive bumps (S8) and singulating (S9). Hereinafter, the manufacturing method of the semiconductor device (200) illustrated in FIG. 3 will now be described with reference to FIGS. 4A to 4F.

As illustrated in FIG. 4A, in the oxidizing (S5a), the plurality of semiconductor chips 100x from which the wafer substrate 10 is removed are oxidized, thereby forming an additional oxide layer 211 on outer surfaces of the oxide layer 110 and the semiconductor dies 120. As the result of the oxidizing, the additional oxide layer 211 may be formed to a predetermined thickness on a first surface 110a and lateral surfaces 110c of the oxide layer 110, made of silicon oxide, and on the lateral surfaces 110c of the semiconductor dies 120. Therefore, the additional oxide layer 211 formed by the oxidizing may be integrally formed with the oxide layer 110 of the semiconductor chips 110x. That is to say, an oxide layer 210 includes the oxide layer 110 of the semiconductor chips 110x and the additional oxide layer 211 formed by the oxidizing and is formed to completely cover a first surface 120a and lateral surfaces 120c of the semiconductor dies 120.

As illustrated in FIGS. 4B and 4C, in the encapsulating (S6), a plurality of semiconductor chips 200x mounted on a carrier 20 and a first surface 20a of the carrier 20 are encapsulated by an encapsulant 140 so as to be completely covered. The encapsulant 140 is formed to completely cover the first surface 20a of the carrier 20, the oxide layer 210 and the BEOL layer 130. That is to say, the encapsulant 140 is formed on the first surface 20a of the carrier 20 to completely cover the individual semiconductor chips 200x mounted on the first surface 20a of the carrier 20. The encapsulant 140 has a planar first surface 140a and a second surface 140b opposite to the first surface 140a and being in contact with the first surface 20a of the carrier 20. The plurality of semiconductor chips 200x spaced apart from each other can be electrically protected from external circumstances by the encapsulant 140.

The encapsulating (S6) may be performed by one selected from the group consisting of general transfer molding, compression molding, injection molding and equivalents thereof, but aspects of the present invention are not limited thereto. The encapsulant 140 may be general epoxy, film, paste and equivalents thereof, but aspects of the present invention are not limited thereto.

In addition, after forming the encapsulant 140, the carrier 20 is removed to expose a second surface 130b of the BEOL layer 130 brought into contact with the first surface 20a of the carrier 20 and a second surface 140b of the encapsulant 140 to the outside.

As illustrated in FIG. 4D, in the forming of the redistribution layer (S7), the redistribution layer 150 is formed to cover the second surface 130b of the BEOL layer 130 and the second surface 140b of the encapsulant 140 so as to be electrically connected to the BEOL layer 130 exposed to the outside. The redistribution layer 150 includes a second dielectric layer 151 and second redistributions 152. The process for forming the redistribution layer 150 may be the same as the forming of the redistribution layer (S7) illustrated in FIG. 2H.

As illustrated in FIG. 4E, in the forming of conductive bumps (S8), a plurality of conductive bumps 160 are formed to make contact with or to be electrically connected to the plurality of second redistributions 152 exposed to the second surface 150b of the redistribution layer 150. The process for forming the conductive bumps 160 may be the same as the forming of the conductive bumps (S8) illustrated in FIG. 2I.

As illustrated in FIG. 4F, in the singulating (S9), the encapsulant 140 and the redistribution layer 150 are diced to be divided into individual semiconductor devices 200 having one or more semiconductor dies 120.

The semiconductor device 200 may easily increase the number of I/O pads by increasing the regions for forming the I/O pads such that the redistribution layer 150 extends to the second surface 140b of the encapsulant 140. In addition, the semiconductor device 200 may completely remove the remaining wafer substrate from the oxide layer 210 and to completely cover the semiconductor dies 120, thereby preventing the leakage of current and reducing the loss of power.

While the semiconductor device and the manufacturing method thereof according to various aspects of the present disclosure have been described with reference to certain supporting embodiments, it will be understood by those skilled in the art that the present invention not be limited to the particular embodiments disclosed, but that the present invention will include all embodiments falling within the scope of the appended claims.

1. A method for manufacturing a semiconductor device, the method comprising:
providing an integrated circuit (IC) die comprising:
an oxide layer comprising first and second oxide surfaces;
a semiconductor layer formed on the oxide layer and comprising first and second semiconductor surfaces, and comprising an IC;
a back end of the line (BEOL) layer comprising first and second BEOL surfaces; and
bond pads exposed by the BEOL layer, wherein:
the first BEOL surface is attached to the first semiconductor surface; and
the first oxide surface is attached to the second semiconductor surface; and
forming conductive bumps electrically coupled to the bond pads,
wherein providing the IC die comprises:
providing the second oxide surface uncovered from semiconductor material.

2. The method of claim 1, wherein:
providing the IC die comprises:
providing the IC die comprising a semiconductor substrate having first and second substrate surfaces,
where the oxide layer comprises an oxide on the semiconductor substrate, formed thereon such that the second oxide surface is attached to the first substrate surface; and
providing the second oxide surface uncovered from semiconductor material comprises:
removing the semiconductor substrate from the oxide layer by one or both of grinding and/or etching.

3. The method of claim 2, wherein:
removing the semiconductor substrate comprises:
partially removing the semiconductor substrate by grinding; and
removing a remainder of the semiconductor substrate by etching.

4. The method of claim 1, further comprising:
encapsulating the IC die with an encapsulant such that the second BEOL surface remains unencapsulated; and
forming a redistribution layer comprising:
a redistribution dielectric layer; and
a redistribution pattern layer;
wherein:
a first redistribution layer side of the redistribution layer is attached to the second BEOL surface and to an encapsulant surface of the encapsulant; and
the conductive bumps are:
attached to a second redistribution layer side of the redistribution layer;
located over the encapsulant; and
electrically coupled to the bond pads of the IC die through the redistribution pattern layer.

5. The method of claim 1, further comprising:
oxidizing at least sidewalls of the semiconductor layer such that the semiconductor layer is covered by oxide on its sidewalls and on its second semiconductor surface.

6. The method of claim 1, further comprising:
encapsulating the IC die;
wherein:
providing the IC die comprises:
providing a wafer having a plurality of IC dies, including the IC die; and
dicing the wafer to separate the plurality of IC dies;
encapsulating the IC die comprises:
mounting the plurality of IC dies on first carrier surface of a carrier; and
encapsulating the plurality of IC dies with an encapsulant such that:
respective side surfaces of the plurality of dies are encapsulated; and
a surface of the encapsulant covers, between the plurality of dies, portions of the first carrier surface,
wherein respective second BEOL surfaces of the plurality of dies remain unencapsulated; and
forming the conductive bumps comprises:
removing the carrier to expose the surface of the encapsulant and the second BEOL surfaces of the plurality of dies; and
forming the conductive bumps over the surface of the encapsulant.

7. A semiconductor device comprising:
a redistribution layer;
a back end of line (BEOL) layer electrically connected to the redistribution layer;
a semiconductor layer comprising an integrated circuit and electrically connected to the BEOL layer;
a top oxide layer covering a top surface of the semiconductor layer;
an encapsulant at least partially encapsulating the top oxide layer, the semiconductor layer, the BEOL layer and a top surface of the redistribution layer; and
conductive bumps formed on a bottom surface of the redistribution layer and electrically connected to the redistribution layer.

8. The semiconductor device of claim 7, wherein:
the integrated circuit comprises a radio frequency device.

9. The semiconductor device of claim 7, wherein:
the redistribution layer is electrically connected to the BEOL layer and covers a bottom surface of the encapsulant.

10. The semiconductor device of claim 7, further comprising:
a side oxide layer formed on sidewalls of the semiconductor layer;

11. The semiconductor device of claim 10, wherein:
the side oxide layer further covers the top oxide layer.

12. The semiconductor device of claim 7, wherein:
the encapsulant contacts a top oxide surface on the top oxide layer.

13. The semiconductor device of claim 7, wherein:
the top oxide layer comprises a bottom oxide surface; and
the semiconductor layer is formed on the bottom oxide surface.

14. The semiconductor device of claim 7, wherein:
the top oxide layer is a semiconductor oxide distinct from an oxide of the semiconductor layer.

15. A semiconductor device comprising:
an integrated circuit (IC) die comprising:
a back end of the line (BEOL) layer comprising first and second BEOL surfaces;
a semiconductor layer on the BEOL layer and comprising first and second semiconductor surfaces, and comprising an IC;
an oxide layer on the semiconductor layer and comprising first and second oxide surfaces; and
bond pads exposed by the BEOL layer, wherein
the first BEOL surface attached to the first semiconductor surface; and
the first oxide surface attached to the second semiconductor surface; and
conductive bumps electrically coupled to the bond pads;
wherein a region from a top surface of the semiconductor device to the second oxide surface is free from semiconductor material.

16. The semiconductor device of claim 15, further comprising:
a redistribution structure comprising:
a redistribution dielectric layer;
a redistribution pattern layer; and
first and second redistribution structure sides,
wherein the conductive bumps are:
attached to the second redistribution structure side; and
electrically coupled to the bond pads of the IC die through the redistribution pattern layer.

17. The semiconductor device of claim 16, wherein:
the redistribution structure is formed on the second BEOL surface.

18. The semiconductor device of claim 16, further comprising:
an encapsulant encapsulating the IC die and comprising:
an encapsulant surface laterally offset and parallel to the second BEOL surface;
wherein:
the second BEOL surface is unencapsulated by the encapsulant;
the first redistribution structure side extends on the second BEOL surface and on the encapsulant surface; and
the conductive bumps are located over the encapsulant surface and offset from the second BEOL surface.

19. The semiconductor device of claim 15, further comprising:
an oxide distinct from the oxide layer and attached to one or both of:
sidewalls of the semiconductor layer; and/or
the second oxide surface of the oxide layer.

20. The semiconductor device of claim 15, wherein:
the semiconductor layer is formed on the first oxide surface.
